(19) United States
(12) Patent Application Publication
(10) Pub. No.: US 2011/0272727 A1
(43) Pub. Date: Nov. 10, 2011

(54) LIGHT-EMITTING DIODE AND METHOD FOR MANUFACTURING THE SAME

(75) Inventors: Chih-Tsung Su, Tainan City (TW); Chun-Lung Tseng, Kaohsiung City (TW); Ching-Wei Chiu, Budai Township (TW); Tao-Chi Chang, Yuanlin Township (TW); Chan-Yang Lu, Tainan City (TW); Jia-Ming Yu, Tainan City (TW); Yi-Chang Yu, Tainan City (TW); Yu-Chen Yang, Tainan City (TW)

(73) Assignee: Epistar Corporation, Hsinchu (TW)

(21) Appl. No.: 13/186,225

(22) Filed: Jul. 19, 2011

Related U.S. Application Data
(63) Continuation-in-part of application No. 12/000,040, filed on Dec. 7, 2007.

(30) Foreign Application Priority Data
Feb. 13, 2007 (TW) 096105301

(51) Int. Cl. H01L 33/60

(52) U.S. Cl. 257/98; 257/E33.072

(57) ABSTRACT

A light-emitting diode and method for manufacturing the same are described. The light-emitting diode comprises: a conductive substrate including a first surface and a second surface opposite to the first surface; a reflector structure comprising a conductive reflector layer bonding to the first surface of the conductive substrate and a conductive distributed Bragg reflector (DBR) structure stacked on the conductive reflector layer; an illuminant epitaxial structure disposed on the reflector structure; a first electrode disposed on a portion of the illuminant epitaxial structure; and a second electrode bonded to the second surface of the conductive substrate.

### RELATED APPLICATIONS

The present application claims the right of priority based on U.S. patent application Ser. No. 12/000,040 entitled “Light-emitting Diode And Method For Manufacturing The Same”, filed on Dec. 7, 2007, which claims the right of priority based on Taiwan Patent Application No. 096105301 entitled “Light-emitting Diode And Method For Manufacturing The Same”, filed on Feb. 13, 2007, and is incorporated herein by reference in its entirety and assigned to the assignee herein.

### TECHNICAL FIELD

The present application relates to an optoelectronic device and a method for manufacturing the same, and more particularly, to a light-emitting diode (LED) and a method for manufacturing the same.

### BACKGROUND

Semiconductor light-emitting devices such as light emitting diodes are formed with semiconductor materials. Semiconductor light emitting devices are minute solid-state light sources that transform electrical energy into light energy. Semiconductor light emitting devices are small in volume, use a low driving voltage, have a rapid response speed, are shockproof, and have long life-time. Semiconductor light emitting devices are also light, thin, and small thereby meeting the needs of various apparatuses, and thus have been widely applied in various electric products used in daily life.

Currently, a well-known method for increasing the light output of a light-emitting diode is to enhance the light extraction of the light-emitting diode. Several methods described in the following may be used to increase the light-extracting efficiency of the light-emitting diode. The first method is to roughen a surface of the light-emitting diode by directly etching the surface to achieve the effect of increasing the light-extracting efficiency of the light-emitting diode. In the surface roughening method, a mask is usually used to protect local areas, and then a wet or dry etching step is performed to roughen the surface. However, in the surface roughening method, the uniformity of the surface roughness is poor. The second method is to change the external form of the light-emitting diode by etching. However, the process of the second method is complicated, so that the process yield is poor. The third method uses a reflective mirror. However, the light emission fabricated with the third method usually has poor electrical quality and poor adhesion between the reflective mirror and the epitaxial layer, so that the operation efficiency and product reliability of the light-emitting diode are substantially degraded thereby decreasing the life-time of the light-emitting diode.

### SUMMARY

One aspect of the present application is to provide a light-emitting diode, which comprises a reflector structure composed of a conductive distributed Bragg reflector (DBR) structure and a conductive reflector layer, so that the reflector structure is conductive, and the reflectivity of the light-emitting diode is increased to enhance the light extraction.

Another aspect of the present application is to provide a method for manufacturing a light-emitting diode, in which a conductive distributed Bragg reflector structure composed of a plurality of transparent conductive layers is formed on an illuminant epitaxial structure. The transparent conductive layers have superior ohmic contact properties and adhesion to the illuminant epitaxial structure, so that the light extraction and the electrical quality are enhanced, thereby increasing the process yield and reliability of the device.

According to the aforementioned aspects, the present application provides a light-emitting diode, comprising: a conductive substrate including a first surface and a second surface on opposite sides; a reflector structure comprising a conductive reflector layer bonding to the first surface of the conductive substrate and a conductive distributed Bragg reflector structure stacked on the conductive reflector layer; an illuminant epitaxial structure disposed on the reflector structure; a first electrode disposed on a portion of the illuminant epitaxial structure; and a second electrode bonded to the second surface of the conductive substrate.

According to a preferred embodiment of the present application, the conductive reflector layer is a metal reflector layer.

According to the aforementioned aspects, the present application provides a light-emitting diode, comprising: a transparent substrate; an illuminant epitaxial structure comprising a first conductivity type semiconductor layer disposed on the transparent substrate, an active layer disposed on a first portion of the first conductivity type semiconductor layer and exposing a second portion of the first conductivity type semiconductor layer, and a second conductivity type semiconductor layer disposed on the active layer, wherein the first conductivity type semiconductor layer and the second conductivity type semiconductor layer are different conductivity types; a reflector structure comprising a conductive distributed Bragg reflector structure disposed on the second conductivity type semiconductor layer, and a conductive reflector layer stacked on the conductive distributed Bragg reflector structure; a second conductivity type electrode disposed on the reflector structure; and a first conductivity type electrode disposed the second portion of the first conductivity type semiconductor layer.

According to a preferred embodiment of the present application, a material of the transparent substrate is selected from the group consisting of sapphire, SiC, Si, ZnO, MgO, AlN, and GaN.

According to the aforementioned aspects, the present application further provides a method for manufacturing a light-emitting diode, comprising: providing a growth substrate; forming an illuminant epitaxial structure on the growth substrate; forming a reflector structure on the illuminant epitaxial structure, wherein the reflector structure comprises a conductive distributed Bragg reflector structure disposed on the illuminant epitaxial structure and a conductive reflector layer disposed on the conductive distributed Bragg reflector structure; bonding a conductive substrate to the conductive reflector layer, wherein the conductive substrate includes a first surface and a second surface on opposite sides, and the first surface of the conductive substrate is connected to the conductive reflector layer; removing the growth substrate to expose the illuminant epitaxial structure; and forming a first electrode and a second electrode respectively on a portion of the illuminant epitaxial structure and the second surface of the conductive substrate.

According to a preferred embodiment of the present application, the conductive distributed Bragg reflector structure comprises a first low refractive index transparent conductive layer disposed on the illuminant epitaxial structure, a high refractive index transparent conductive layer stacked on the first low refractive index transparent conductive layer, and a second low refractive index transparent conductive layer stacked on the high refractive index transparent conductive layer.

According to the aforementioned aspects, the present application further provides a method for manufacturing a light-emitting diode, comprising: providing a transparent substrate; forming an illuminant epitaxial structure on the transparent substrate, wherein the illuminant epitaxial structure comprises a first conductivity type semiconductor layer, an active layer and a second conductivity type semiconductor layer stacked in sequence, wherein the first conductivity type semiconductor layer and the second conductivity type semiconductor layer are different conductivity types; defining the illuminant epitaxial structure to expose a portion of the first conductivity type semiconductor layer; forming a reflector structure on the second conductivity type semiconductor layer, wherein the reflector structure comprises a conductive distributed Bragg reflector structure disposed on the second conductivity type semiconductor layer, and a conductive reflector layer stacked on the conductive distributed Bragg reflector structure; and forming a first conductivity type electrode and a second conductivity type electrode respectively on the exposed portion of the first conductivity type semiconductor layer and the conductive reflector layer.

According to a preferred embodiment of the present application, the conductive distributed Bragg reflector structure is a multi-layer stacked structure, and the multi-layer stacked structure comprises a plurality of low refractive index transparent conductive layers and a plurality of high refractive index transparent conductive layers stacked alternately.

According to the aforementioned aspects, the present application provides a light-emitting diode, comprising: a reflector structure comprising a metal reflector layer and a first distributed Bragg reflector (DBR) structure on the metal reflector layer, wherein the first DBR structure comprises one or more first layers and one or more second layers stacked alternately; and an illuminant epitaxial structure on the reflector structure; wherein at least one layer in the first DBR structure comprises one material with thermal conductivity greater than 200 W/m·K.

According to the aforementioned aspects, the present application further comprises a substrate between the reflector structure and the illuminant epitaxial structure, wherein the substrate is more adjacent to the first DBR structure than the metal reflector.

According to the aforementioned aspects, the present application further comprises a substrate below the illuminant epitaxial structure, wherein the substrate is more adjacent to the metal reflector than the first DBR structure.

According to a preferred embodiment of the present application, wherein the refractive index of the first layers of the first DBR structure is smaller than 2, and the refractive index of the second layers of the first DBR structure is greater than 2.

### BRIEF DESCRIPTION OF THE DRAWINGS

The foregoing aspects and many of the attendant advantages of this application are more readily appreciated as the same become better understood by reference to the following detailed description, when taken in conjunction with the accompanying drawings, wherein:

FIG. 1A through FIG. 3 are schematic flow diagrams showing the process for manufacturing a light-emitting diode in accordance with a preferred embodiment of the present application;

FIG. 1B shows a cross-sectional view of a light-emitting diode structure in accordance with a preferred embodiment of the present application;

FIG. 4 through FIG. 6 are schematic flow diagrams showing the process for manufacturing a light-emitting diode in accordance with another preferred embodiment of the present application;

FIG. 7 through FIG. 9 are schematic flow diagrams showing the process for manufacturing a light-emitting diode in accordance with another preferred embodiment of the present application;

FIG. 10 through FIG. 12 are schematic flow diagrams showing the process for manufacturing a light-emitting diode in accordance with another preferred embodiment of the present application;

FIG. 13 shows a cross-sectional view of a light-emitting diode structure in accordance with another embodiment of the present application; and

FIG. 14 shows a cross-sectional view of a light-emitting diode structure in accordance with another embodiment of the present application.

### DETAILED DESCRIPTION OF THE PREFERRED EMBODIMENTS

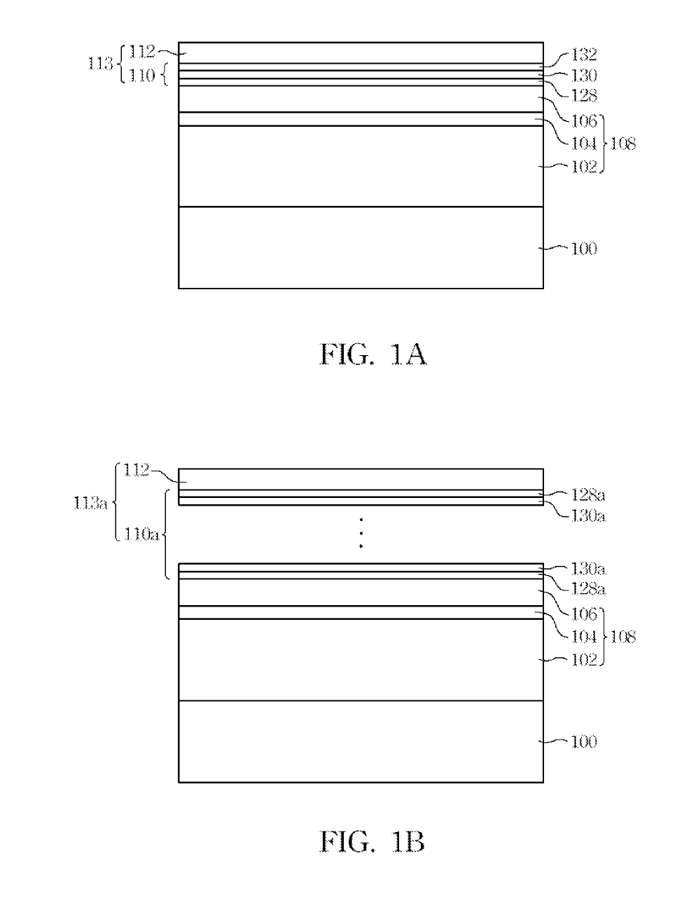

The present application discloses a light-emitting diode and a method for manufacturing the same. In order to make the illustration of the present application more explicit, the following description is stated with reference to FIG. 1A through FIG. 9.

FIG. 1A through FIG. 3 are schematic flow diagrams showing the process for manufacturing a light-emitting diode in accordance with a preferred embodiment of the present application. In an exemplary embodiment, a growth substrate 100 is provided for the epitaxial growth of epitaxial materials formed thereon, wherein a material of the growth substrate 100 may be sapphire, SiC, Si, ZnO, MgO, MN, or GaN. An illuminant epitaxial structure 108 is grown on a surface of the growth substrate 100 by, for example, a metal organic chemical vapor deposition (MOCVD) method, a liquid phase deposition (LPD) method, or a molecular beam epitaxy (MBE) method. In an embodiment, the illuminant epitaxial structure 108 comprises a first conductivity type semiconductor layer 102, an active layer 104 and a second conductivity type semiconductor layer 106 stacked on the surface of the growth substrate 100 in sequence. In the present exemplary embodiment, the first conductivity type and the second conductivity type are different conductivity types. For example, the first conductivity type is n-type, and the second conductivity type is p-type.

Next, transparent conductive layers with different refractive indexes are alternately deposited on the second conductivity type semiconductor layer 106 of the illuminant epitaxial structure 108 by, for example, an evaporation method to form a conductive distributed Bragg reflector structure 110. The conductive distributed Bragg reflector structure 110 may be composed of three or more transparent conductive layers with a high refractive index and a low refractive index stacked alternately, so that the light reflection is formed by the refractive index difference between the low refractive index layer and the high refractive index layer. In the present exemplary embodiment, the conductive distributed Bragg reflector structure 110 includes a transparent conductive layer 128 with a first low refractive index disposed on the second conductivity type semiconductor layer 106 of the illuminant epitaxial structure 108, a transparent conductive layer 130 with a high refractive index stacked on the transparent conductive layer 128, and a transparent conductive layer 132 with a second low refractive index stacked on the transparent conductive layer 130, as shown in FIG. 1A. The first low refractive index of the transparent conductive layer 128 may be different from or the same as the second low refractive index of the transparent conductive layer 132. Furthermore, the transparent conductive layer 128 with a first low refractive index and the transparent conductive layer 132 with a second low refractive index may be composed of the same material, or may be composed of different materials. A material of the conductive distributed Bragg reflector structure 110 is selected from the group consisting of ITO, CTO, ZnO, In₂O₃, SnO₂, CuAlO₂, CuGaO₂, and SrCu₂O₂. Then, a conductive reflector layer 112 is formed to cover the conductive distributed Bragg reflector structure 110, so as to form the structure shown in FIG. 1A. The conductive distributed Bragg reflector structure 110 and the conductive reflector layer 112 comprise a reflector structure 113. The conductive reflector layer 112 is preferably a metal reflector layer, and a material of the conductive reflector layer 112 is, for example, Al, Au, Pt, Zn, Ag, Ni, Ge, In, Sn, or alloys of the aforementioned metals.

In another exemplary embodiment of the present application, referring to FIG. 1B, in the light-emitting diode structure, a conductive distributed Bragg reflector structure 110a is composed of a plurality of transparent conductive layers 128a with a low refractive index and a plurality of transparent conductive layers 130a with a high refractive index stacked alternately. The conductive distributed Bragg reflector structure 110a in the exemplary embodiment is composed of several transparent conductive layers 128a composed of the same kind of material and the several transparent conductive layers 130a composed of the same kind of material stacked alternately. However, the conductive distributed Bragg reflector structure may be composed of several transparent conductive layers with low refractive indexes composed of different materials or incompletely different materials and several transparent conductive layers with high refractive indexes composed of different materials or incompletely different materials. Similarly, after the conductive distributed Bragg reflector structure 110a is completed, a conductive reflector layer 112 is formed to cover the conductive distributed Bragg reflector structure 110a, so as to form the structure shown in FIG. 1B. The conductive distributed Bragg reflector structure 110a and the conductive reflector layer 112 comprise a reflector structure 113a.

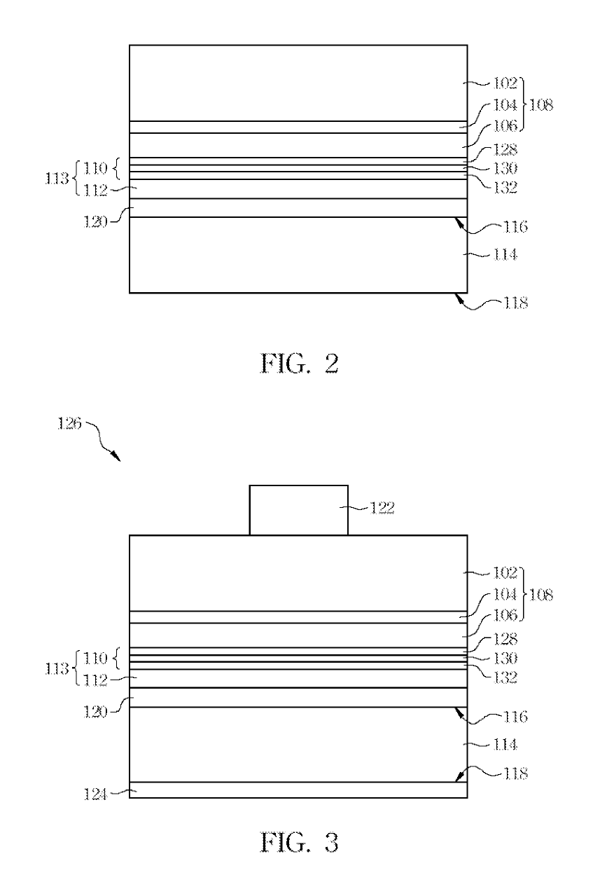

In the present exemplary embodiment, after the reflector structure 113 is completed, a conductive substrate 114 is provided, wherein the conductive substrate 114 includes a surface 116 and a surface 118 on opposite sides. For example, a material of the conductive substrate 114 is silicon or metal. Then, the conductive substrate 114 is bonded to the conductive reflector layer 112 of the reflector structure 113. In the present exemplary embodiment, a conductive bonding layer 120 may be used to bond the conductive substrate 114 with the conductive reflector layer 112. The conductive bonding layer 120 may be initially formed on the surface 116 of the conductive substrate 114, or the conductive bonding layer 120 may be initially formed on the conductive reflector layer 112, then the conductive bonding layer 120 bonds the conductive substrate 114 and the conductive reflector layer 112. In an embodiment, a material of the conductive bonding layer 120 may be selected from Al, Au, Pt, Zn, Ag, Ni, Ge, In, Sn, Ti, Pb, Cu, Pd, or alloys of the aforementioned metals. In another embodiment, a material of the conductive bonding layer 120 may be silver glue, spontaneous conductive polymer or polymer materials mixed with conductive materials. After the conductive substrate 114 is bonded to the reflector structure 113, a chemical etching method or a polishing method removes the growth substrate 100, so as to expose the first conductivity type semiconductor layer 102 of the illuminant epitaxial structure 108, as shown in FIG. 2.

Next, an electrode 122 is formed on a portion of the first conductivity type semiconductor layer 102 of the illuminant epitaxial structure 108, wherein the electrode 122 is the first conductivity type. For example, a material of the electrode 122 is In, Al, Ti, Au, W, InSn, TiN, WSi, PtIn₂, Nd/Al, Ni/Si, Pd/Al, Ta/Al, Ti/Ag, Ta/Ag, Ti/Al, Ti/Au, Ti/TiN, Zr/ZrN, Au/Ge/Ni, Cr/Ni/Au, Ni/Cr/Au, Ti/Pd/Au, Ti/Pt/Au, Ti/Al/Ni/Au, Au/Si/Ti/Au/Si, or Au/Ni/Ti/Si/Ti. Furthermore, an electrode 124 is formed on the surface 118 of the conductive substrate 114, such that the electrode 122 and the electrode 124 are respectively on opposite sides of the illuminant epitaxial structure 108, wherein the electrode 124 is the second conductivity type. Now, the fabrication of a light-emitting diode 126 is substantially completed, as shown in FIG. 3. For example, a material of the electrode 124 is Ni/Au, NiO/Au, Pd/Ag/Au/Ti/Au, Pt/Ru, Ti/Pt/Au, Pd/Ni, Ni/Pd/Au, Pt/Ni/Au, Ru/Au, Nb/Au, Co/Au, Pt/Ni/Au, Ni/Pt, NiIn, or Pt₃In₇.

The transparent conductive layers of the conductive distributed Bragg reflector structure have better ohmic contact property and adhesion to the illuminant epitaxial structure, so that the electrical quality and the operational reliability of the light-emitting diode are enhanced. In addition, the distributed Bragg reflector structure formed by alternately stacking several low/high refractive index transparent conductive layers is conductive, and enhances the reflectivity to increase the light extraction of the light-emitting diode.

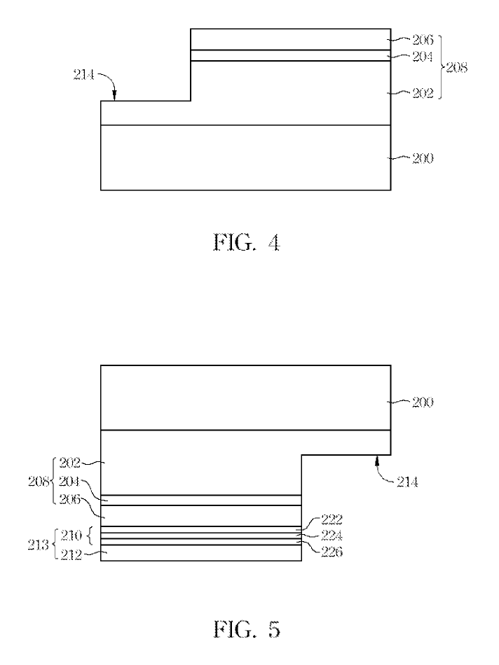

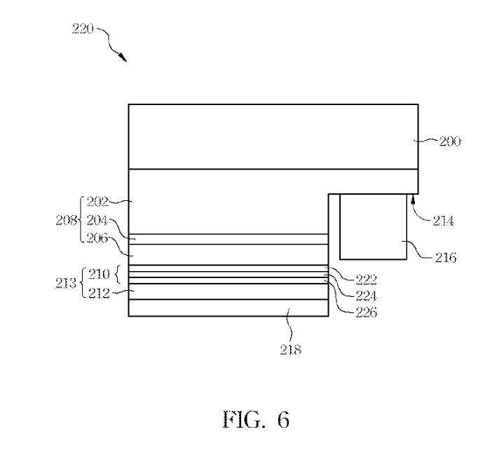

FIG. 4, FIG. 5 and FIG. 6 are schematic flow diagrams showing the manufacturing process of a light-emitting diode in accordance with another preferred embodiment of the present application. In an exemplary embodiment, a growth substrate 200 is provided for the epitaxial growth of epitaxial materials formed thereon. In the present exemplary embodiment, the growth substrate 200 is a transparent substrate, and a material of the growth substrate 200 may be sapphire, SiC, Si, ZnO, MgO, MN, or GaN. An illuminant epitaxial structure 208 is grown on a surface of the growth substrate 200 by, for example, a metal organic chemical vapor deposition method, a liquid phase deposition method or a molecular beam epitaxy method. In an embodiment, the illuminant epitaxial structure 208 comprises a first conductivity type semiconductor layer 202, an active layer 204, and a second conductivity type semiconductor layer 206 stacked on the surface of the growth substrate 200 in sequence. In the present exemplary embodiment, the first conductivity type and the second conductivity type are different conductivity types. For example, the first conductivity type is n-type, and the second conductivity type is p-type. Next, a pattern-defining step is performed on the illuminant epitaxial structure 208 by, for example, a photolithography and etching method. In the pattern defining step, a portion of the second conductivity type semiconductor layer 206 and a portion of the active layer 204 are removed until a portion surface 214 of the first conductivity type semiconductor layer 202 is exposed, as shown in FIG. 4.

After defining the illuminant epitaxial structure 208, transparent conductive layers with different refractive indexes are alternately deposited on the second conductivity type semiconductor layer 206 of the illuminant epitaxial structure 208 by, for example, an evaporation method to form a conductive distributed Bragg reflector structure 210. The conductive distributed Bragg reflector structure 210 may be composed of three or more transparent conductive layers with a high refractive index and a low refractive index stacked alternately, so that the light reflection is formed by the refractive index difference between the low refractive index layer and the high refractive index layer. In the present exemplary embodiment, the conductive distributed Bragg reflector structure 210 includes a transparent conductive layer 222 with a first low refractive index disposed on the second conductivity type semiconductor layer 206 of the illuminant epitaxial structure 208, a transparent conductive layer 224 with a high refractive index stacked on the transparent conductive layer 222, and a transparent conductive layer 226 with a second low refractive index stacked on the transparent conductive layer 224, as shown in FIG. 5. The first low refractive index of the transparent conductive layer 222 may be different from or the same as the second low refractive index of the transparent conductive layer 226. Furthermore, the transparent conductive layer 222 with a first low refractive index and the transparent conductive layer 226 with a second low refractive index may be composed of the same kind of material, or may be composed of different materials. A material of the conductive distributed Bragg reflector structure 210 is selected from the group consisting of ITO, CTO, ZnO, In₂O₃, SnO₂, CuAlO₂, CuGaO₂, and SrCu₂O₂. Then, a conductive reflector layer 212 is formed to cover the conductive distributed Bragg reflector structure 210, so as to form the structure shown in FIG. 5. The conductive distributed Bragg reflector structure 210 and the conductive reflector layer 212 comprise a reflector structure 213. The conductive reflector layer 212 is preferably a metal reflector layer, and a material of the conductive reflector layer 212 is, for example, Al, Au, Pt, Zn, Ag, Ni, Ge, In, Sn, or alloys of the aforementioned metals.

Next, an electrode 216 is formed on the exposed surface 214 of the first conductivity type semiconductor layer 202 of the illuminant epitaxial structure 208, wherein the electrode 216 is a first conductivity type. For example, a material of the electrode 216 is In, Al, Ti, Au, W, InSn, TiN, WSi, PtIn₂, Nd/Al, Ni/Si, Pd/Al, Ta/Al, Ti/Ag, Ta/Ag, Ti/Al, Ti/Au, Ti/TiN, Zr/ZrN, Au/Ge/Ni, Cr/Ni/Au, Ni/Cr/Au, Ti/Pd/Au, Ti/Pt/Au, Ti/Al/Ni/Au, Au/Si/Ti/Au/Si, or Au/Ni/Ti/Si/Ti. Furthermore, an electrode 218 is formed on the conductive reflector layer 212 of the reflector structure 213, such that the electrode 216 and the electrode 218 are on the same side of the illuminant epitaxial structure 208, wherein the electrode 218 is second conductivity type. Now, the fabrication of a light-emitting diode 220 is substantially completed, as shown in FIG. 6. For example, a material of the electrode 218 is Ni/Au, NiO/Au, Pd/Ag/Au/Ti/Au, Pt/Ru, Ti/Pt/Au, Pd/Ni, Ni/Pd/Au, Pt/Ni/Au, Ru/Au, Nb/Au, Co/Au, Pt/Ni/Au, Ni/Pt, NiIn, or Pt₃In₇.

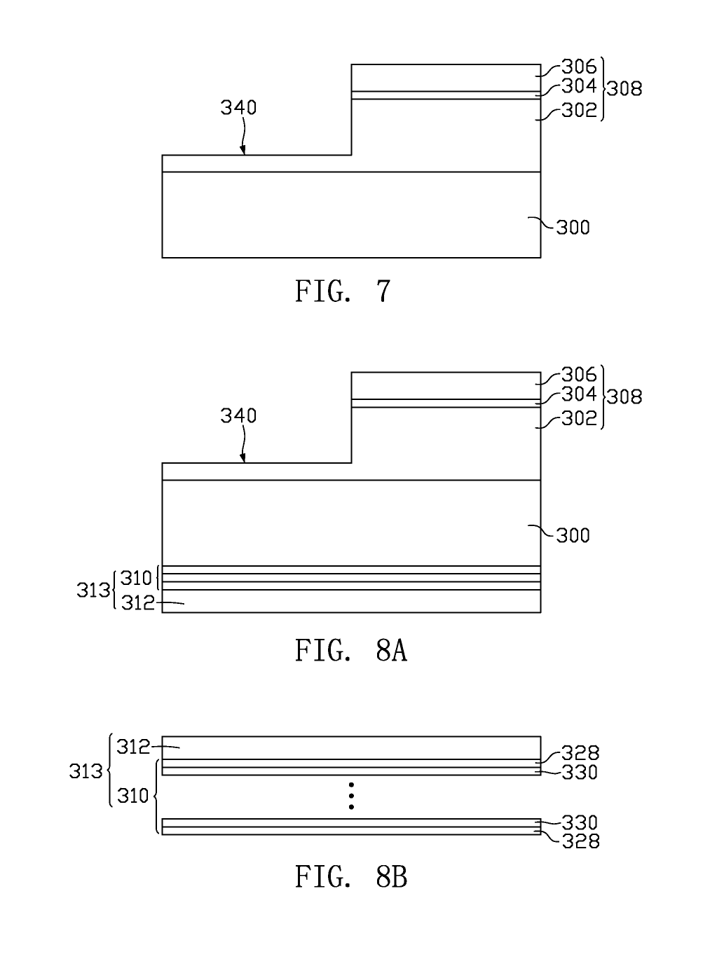

FIG. 7 through FIG. 9 are schematic flow diagrams showing the process for manufacturing a light-emitting diode 390 in accordance with another preferred embodiment of the present application. In an embodiment, a growth substrate 300 with a first surface and a second surface is provided for the epitaxial growth of epitaxial materials formed thereon, wherein a material of the growth substrate 300 may be sapphire, SiC, Si, ZnO, MgO, AlN, or GaN. An illuminant epitaxial structure 308 is grown on the first surface of the growth substrate 300 by, for example, a metal organic chemical vapor deposition (MOCVD) method, a liquid phase deposition (LPD) method, or a molecular beam epitaxy (MBE) method. In an embodiment, the illuminant epitaxial structure 308 comprises a first conductivity type semiconductor layer 302, an active layer 304 and a second conductivity type semiconductor layer 306 stacked on the first surface of the growth substrate 300 in sequence. In the present exemplary embodiment, the first conductivity type and the second conductivity type are different conductivity types. For example, the first conductivity type is n-type, and the second conductivity type is p-type.

Next, a pattern-defining step is performed on the illuminant epitaxial structure 308 by, for example, a photolithography and etching method. In the pattern defining step, a portion of the second conductivity type semiconductor layer 306 and a portion of the active layer 304 are removed until a partial surface 340 of the first conductivity type semiconductor layer 302 is exposed, as shown in FIG. 7.

Next, a first distributed Bragg reflector (DBR) structure 310 comprises one or more first layers and one or more second layers stacked alternately on the second surface of the growth substrate 300 by, for example, an evaporation method. As shown in FIG. 8B, the first distributed Bragg reflector structure 310 is composed of a plurality of first layers 328 with a low refractive index and a plurality of second layers 330 with a high refractive index stacked alternately. The refractive index of the first layers 328 is smaller than 2, and the refractive index of the second layers 330 is greater than 2. In another embodiment, the refractive index of the first layers 328 is smaller than 2, and the refractive index of the second layers 330 is greater than 2.4. Furthermore, the refractive index difference of the first layers 328 and the second layers 330 is greater than 0.6. The first layers 328 in the first distributed Bragg reflector structure comprise oxide or fluoride. The second layers 330 in the first distributed Bragg reflector structure comprise diamond or diamond-like-carbon (DLC). In another embodiment, at least one layer in the first distributed Bragg reflector structure comprises one material with the thermal conductivity greater than 200 W/m·K, or optionally greater than 400 W/m·K. The first distributed Bragg reflector structure 310 comprises at least 5 layers, and the thickness of the first layers 328 or the second layers 330 is approximate nλ/4, wherein λ is a dominant wavelength of a light emitted by the illuminant epitaxial structure 308, and n is an integer not less than 1.

Similarly, after the first distributed Bragg reflector structure 310 is formed, a metal reflector layer 312 is formed below the first distributed Bragg reflector structure 310, so as to form a reflector structure 313 shown in FIG. 8A. The metal reflector layer 312 is preferably a metal layer, for example, Al, Au, Pt, Zn, Ag, Ni, Ge, In, Sn, or alloys of the aforementioned metals, so the reflector structure 313 has high thermal conductivity and high reflectivity.

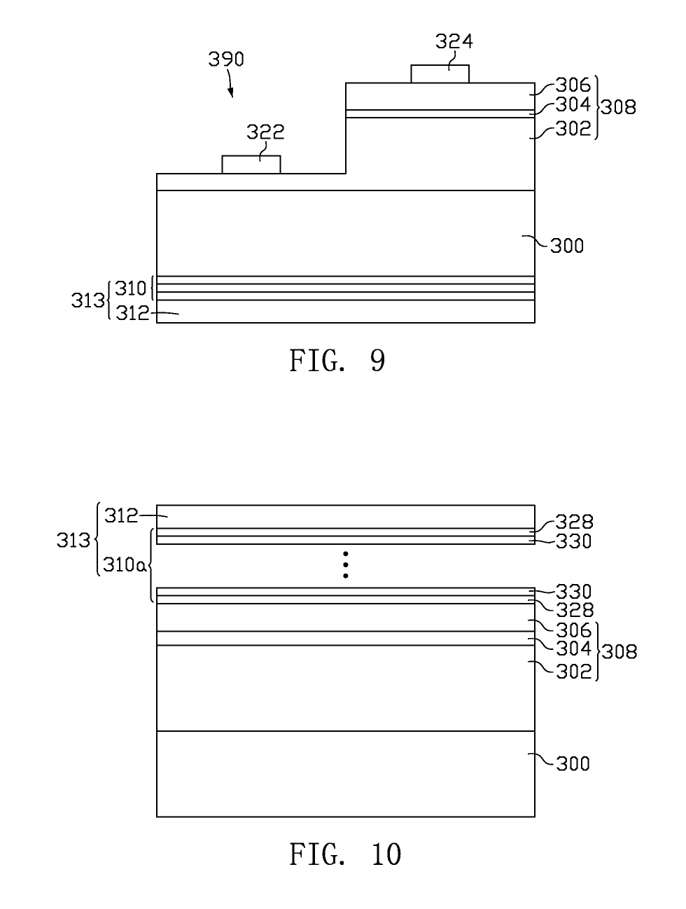

Next, an electrode 322 is formed on the exposed surface 340 of the first conductivity type semiconductor layer 302 of the illuminant epitaxial structure 308, wherein the electrode 322 is a first conductivity type. For example, a material of the electrode 322 is In, Al, Ti, Au, W, InSn, TiN, WSi, PtIn₂, Nd/Al, Ni/Si, Pd/Al, Ta/Al, Ti/Ag, Ta/Ag, Ti/Al, Ti/Au, Ti/TiN, Zr/ZrN, Au/Ge/Ni, Cr/Ni/Au, Ni/Cr/Au, Ti/Pd/Au, Ti/Pt/Au, Ti/Al/Ni/Au, Au/Si/Ti/Au/Si, or Au/Ni/Ti/Si/Ti. Furthermore, an electrode 324 is formed on the surface of the second conductivity type semiconductor layer 306 of the illuminant epitaxial structure 308, such that the electrode 322 and the electrode 324 are on the same side of the illuminant epitaxial structure 308, wherein the electrode 324 is second conductivity type. For example, a material of the electrode 324 is Ni/Au, NiO/Au, Pd/Ag/Au/Ti/Au, Pt/Ru, Ti/Pt/Au, Pd/Ni, Ni/Pd/Au, Pt/Ni/Au, Ru/Au, Nb/Au, Co/Au, Pt/Ni/Au, Ni/Pt, NiIn, or Pt₃In₇. Now, the fabrication of a light-emitting diode 390 is substantially completed, as shown in FIG. 9.

FIG. 10 through FIG. 12 are schematic flow diagrams showing the process for manufacturing a light-emitting diode 400 in accordance with another preferred embodiment of the present application. In this embodiment, the illuminant epitaxial structure 308 comprises a first conductivity type semiconductor layer 302, an active layer 304 and a second conductivity type semiconductor layer 306 stacked on the first surface of the growth substrate 300 in sequence.

Next, a first distributed Bragg reflector (DBR) structure 310a comprises one or more first layers and one or more second layers stacked alternately on the second conductivity type semiconductor layer 306 by, for example, an evaporation method. As shown in FIG. 10, the first distributed Bragg reflector structure 310a is composed of a plurality of first layers 328 with a low refractive index and a plurality of second layers 330 with a high refractive index stacked alternately. The refractive index of the first layers 328 is smaller than 2, and the refractive index of the second layers 330 is greater than 2. In another embodiment, the refractive index of the first layers 328 is smaller than 2, and the refractive index of the second layers 330 is greater than 2.4. Furthermore, the refractive index difference of the first layers 328 and the second layers 330 is greater than 0.6. The first layers 328 in the first distributed Bragg reflector structure comprise oxide or fluoride. The second layers 330 in the first distributed Bragg reflector structure comprise diamond or diamond-like-carbon (DLC). In another embodiment, at least one layer in the first distributed Bragg reflector structure comprises one material with the thermal conductivity greater than 200 W/m·K, or optionally greater than 400 W/m·K. The first distributed Bragg reflector structure 310a comprises at least 5 layers, and the thickness of the first layers 328 or the second layers 330 is approximate nλ/4, wherein λ is a dominant wavelength of a light emitted by the illuminant epitaxial structure 308, and n is an integer not less than 1.

Similarly, after the first distributed Bragg reflector structure 310a is formed, a metal reflector layer 312 is formed on the first distributed Bragg reflector structure 310a. The first distributed Bragg reflector structure 310a and the metal reflector layer 312 form a reflector structure 313. The metal reflector layer 312 is preferably a metal layer, for example, Al, Au, Pt, Zn, Ag, Ni, Ge, In, Sn, or alloys of the aforementioned metals, so the reflector structure 313 has high thermal conductivity and high reflectivity.

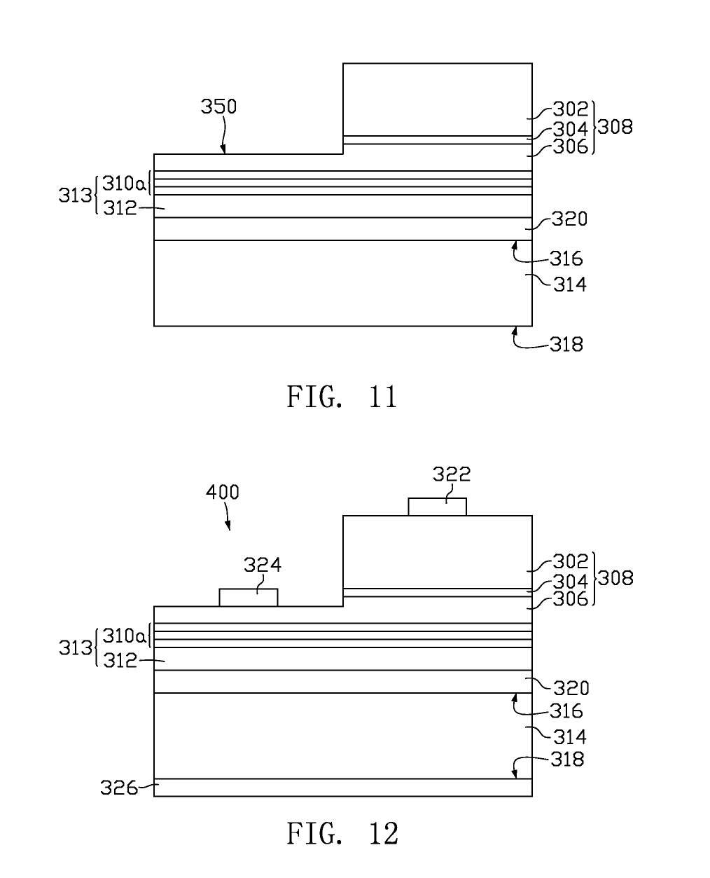

In the present embodiment, after the reflector structure 313 is formed, a substrate 314 is provided, wherein the substrate 314 includes a first surface 316 and a second surface 318 opposite to the first surface. The material of the substrate 314 can be silicon or metal. Then, the substrate 314 is bonded to the metal reflector layer 312 of the reflector structure 313. In the present embodiment, a bonding layer 320 is used to attach the substrate 314 to the metal reflector layer 312. The bonding layer 320 may be initially formed on the first surface 316 of the substrate 314, or the bonding layer 320 may be initially formed below the metal reflector layer 312, then the bonding layer 320 bonds the substrate 314 and the metal reflector layer 312. In an embodiment, a material of the bonding layer 320 may be selected from Al, Au, Pt, Zn, Ag, Ni, Ge, In, Sn, Ti, Pb, Cu, Pd, or alloys of the aforementioned metals. In another embodiment, the material of the bonding layer 320 may be silver glue, spontaneous conductive polymer or polymer materials mixed with conductive materials. After the substrate 314 is bonded to the reflector structure 313, the growth substrate 300 is removed by chemical etching method or a polishing method, so the first conductivity type semiconductor layer 302 of the illuminant epitaxial structure 308 is exposed. Next, a pattern-defining step is performed on the illuminant epitaxial structure 308 by, for example, a photolithography and etching method. In the pattern defining step, a portion of the first conductivity type semiconductor layer 302 and a portion of the active layer 304 are removed until a partial surface 350 of the second conductivity type semiconductor layer 306 is exposed, as shown in FIG. 11.

Then a solder layer 326 may be formed on the second surface 318 of the substrate 314. Next, an electrode 324 is formed on the exposed surface 350 of the second conductivity type semiconductor layer 306 of the illuminant epitaxial structure 308, wherein the electrode 324 is a second conductivity type. For example, a material of the electrode 324 is Ni/Au, NiO/Au, Pd/Ag/Au/Ti/Au, Pt/Ru, Ti/Pt/Au, Pd/Ni, Ni/Pd/Au, Pt/Ni/Au, Ru/Au, Nb/Au, Co/Au, Pt/Ni/Au, Ni/Pt, NiIn, or Pt₃In₇. Furthermore, an electrode 322 is formed on the surface of the first conductivity type semiconductor layer 302 of the illuminant epitaxial structure 308, such that the electrode 322 and the electrode 324 are on the same side of the illuminant epitaxial structure 308, wherein the electrode 322 is first conductivity type. For example, a material of the electrode 322 is In, Al, Ti, Au, W, InSn, TiN, WSi, PtIn₂, Nd/Al, Ni/Si, Pd/Al, Ta/Al, Ti/Ag, Ta/Ag, Ti/Al, Ti/Au, Ti/TiN, Zr/ZrN, Au/Ge/Ni, Cr/Ni/Au, Ni/Cr/Au, Ti/Pd/Au, Ti/Pt/Au, Ti/Al/Ni/Au, Au/Si/Ti/Au/Si, or Au/Ni/Ti/Si/Ti. Now, the fabrication of a light-emitting diode 400 is substantially completed, as shown in FIG. 12.

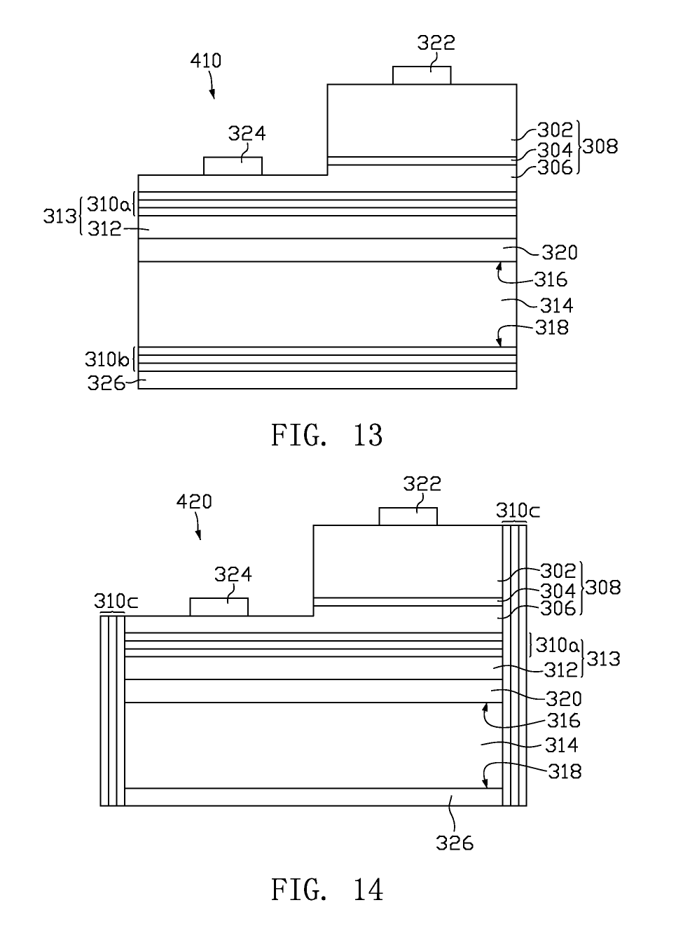

FIG. 13 shows a cross-sectional view of a light-emitting diode 410 structure in accordance with another embodiment of the present application. As FIG. 11 shows, after the substrate 314 is bonded to the reflector structure 313 by the bonding layer 320, a second distributed Bragg reflector (DBR) structure 310b comprises one or more first layers and one or more second layers stacked alternately below the second surface 318 of the substrate 314 by, for example, an evaporation method. As shown in FIG. 13, the second distributed Bragg reflector structure 310b is composed of a plurality of first layers 328 with a low refractive index and a plurality of second layers 330 with a high refractive index stacked alternately. The refractive index, materials, thickness, layers, thermal conductivity of the first layers 328 and the second layers 330 are the same with the above embodiments.

FIG. 14 shows a cross-sectional view of a light-emitting diode 420 structure in accordance with another embodiment of the present application. After the fabrication of a light-emitting diode 400 is substantially performed, as shown in FIG. 12, a third distributed Bragg reflector (DBR) structure 310c comprising one or more first layers and one or more second layers stacked alternately on the sidewall of the light-emitting diode is further formed. As shown in FIG. 14, the third distributed Bragg reflector structure 310c is composed of a plurality of first layers 328 with a low refractive index and a plurality of second layers 330 with a high refractive index stacked alternately. The refractive index, materials, thickness, layers, thermal conductivity of the first layers 328 and the second layers 330 are the same with the above embodiments.

According to the aforementioned description, one advantage of the light-emitting diode in the aforementioned exemplary embodiment is that the light-emitting diode comprises a reflector structure composed of a conductive distributed Bragg reflector structure and a conductive reflector layer, so that the reflector structure is conductive, and the reflectivity of the light-emitting diode is increased to enhance the light extraction.

According to the aforementioned description, one advantage of the light-emitting diode in the aforementioned exemplary embodiment is that the light-emitting diode comprises a reflector structure composed of a distributed Bragg reflector structure and a metal reflector layer, so that the reflector structure is high thermal conductive, and the reflectivity of the light-emitting diode is increased to enhance the light extraction.

According to the aforementioned description, one advantage of the method for manufacturing a light-emitting diode in the aforementioned exemplary embodiment is that a conductive distributed Bragg reflector structure composed of a plurality of transparent conductive layers is formed on an illuminant epitaxial structure, and the transparent conductive layers have better ohmic contact property and adhesion to the illuminant epitaxial structure, so that the light extraction and the electrical quality are enhanced, thereby increasing the process yield and reliability of the device.

As is understood by a person skilled in the art, the foregoing preferred embodiments of the present application are illustrated of the present application rather than limiting of the present application. It is intended to cover various modifications and similar arrangements included within the spirit and scope of the appended claims, the scope of which should be accorded the broadest interpretation so as to encompass all such modifications and similar structure.

What is claimed is:

1. A light-emitting diode, comprising:
a reflector structure comprising a metal reflector layer and a first distributed Bragg reflector (DBR) structure on the metal reflector layer, wherein the first DBR structure comprises one or more first layers and one or more second layers stacked alternately; and
an illuminant epitaxial structure on the reflector structure;
wherein at least one layer in the first DBR structure comprises one material with the thermal conductivity greater than 200 W/m·K.

2. The light-emitting diode according to claim 1, further comprising a substrate between the reflector structure and the illuminant epitaxial structure, wherein the substrate is more adjacent to the first DBR structure than the metal reflector.

3. The light-emitting diode according to claim 1, further comprising a substrate below the illuminant epitaxial structure, wherein the substrate is more adjacent to the metal reflector than the first DBR structure.

4. The light-emitting diode according to claim 1, wherein the illuminant epitaxial structure comprising:
a second conductivity type semiconductor layer on the first DBR structure;
an active layer on a first portion of the second conductivity type semiconductor layer and exposing a second portion of the second conductivity type semiconductor layer; and
a first conductivity type semiconductor layer on the active layer, wherein
the first conductivity type semiconductor layer and the second conductivity type semiconductor layer are different conductivity types.

5. The light-emitting diode according to claim 4, further comprising:
a first electrode on the first conductivity type semiconductor layer; and
a second electrode on the second portion of the second conductivity type semiconductor layer.

6. The light-emitting diode according to claim 1, wherein a material of the metal reflector layer is selected from the group consisting of Al, Au, Pt, Zn, Ag, Ni, Ge, In, Sn, and alloys thereof.

7. The light-emitting diode according to claim 3, further comprising a bonding layer between the substrate and the reflector structure.

8. The light-emitting diode according to claim 1, further comprising a second DBR structure on the sidewall of the illuminant epitaxial structure; wherein the second DBR structure consists of one or more first layers and one or more second layers stacked alternately.

9. The light-emitting diode according to claim 1, wherein the refractive index of the first layers is smaller than 2, and the refractive index of the second layers is greater than 2.

10. The light-emitting diode according to claim 1, wherein the refractive index of the first layers is smaller than 2, and the refractive index of the second layers is greater than 2.4.

11. The light-emitting diode according to claim 1, wherein the refractive index difference of the first layers and the second layers is greater than 0.6.

12. The light-emitting diode according to claim 1, wherein the first layers in the first DBR structure comprise oxide or fluoride.

13. The light-emitting diode according to claim 1, wherein the second layers in the first DBR structure comprise diamond or diamond-like-carbon (DLC).

14. The light-emitting diode according to claim 1, wherein the first DBR structure comprises at least 5 layers.

15. The light-emitting diode according to claim 1, wherein the thickness of the first layers or the second layers is approximate nλ/4, wherein λ is a dominant wavelength of a light emitted by the illuminant epitaxial structure; and n is an integer not less than 1.

16. The light-emitting diode according to claim 8, wherein the thickness of the first layers or the second layers is approximate nλ/4, wherein λ is a dominant wavelength of a light emitted by the illuminant epitaxial structure; and n is an integer not less than 1.

17. The light-emitting diode according to claim 1, wherein at least one layer in the first DBR structure comprises one material with the thermal conductivity greater than 400 W/m·K.
